(19) United States
(12) Patent Application Publication
(10) Pub. No.: US 2025/0210315 A1
(43) Pub. Date: Jun. 26, 2025

(54) MODULAR PROCESSING CHAMBERS AND RELATED HEATING CONFIGURATIONS, METHODS, APPARATUS, AND MODULES FOR SEMICONDUCTOR MANUFACTURING

(71) Applicant: Applied Materials, Inc., Santa Clara, CA (US)

(72) Inventors: Ala MORADIAN, Sunnyvale, CA (US); Ananth Nuggehalli BHOJ, Round Rock, TX (US); Yunho KIM, Milpitas, CA (US); Saurabh CHOPRA, Santa Clara, CA (US)

(21) Appl. No.: 18/393,086

(22) Filed: Dec. 21, 2023

(51) Int. Cl. H01J 37/32

(52) U.S. Cl. CPC H01J 37/32522; H01J 37/321; H01J 37/32357; H01J 37/3244; H01J 2237/332

(57) ABSTRACT

The present disclosure relates to heaters, and related chamber kits and processing chambers, for semiconductor manufacturing. In one or more embodiments, the chamber body includes an inject section and an exhaust section, a plasma source assembly, a substrate support disposed in the processing volume, and one or more heat sources configured to heat the processing volume. The chamber body and the plasma source assembly at least partially define a processing volume. The plasma source assembly includes a sidewall and a gas injection insert disposed within the sidewall. The sidewall and the gas injection insert define a plasma source interior volume. The gas injection insert and the sidewall at least partially defining one or more gas injection channels therebetween. A plasma generator is disposed around the sidewall.

### BACKGROUND

### Field

The present disclosure relates to heaters, and related chamber kits and processing chambers, for semiconductor manufacturing.

### Description of the Related Art

Semiconductor substrates are processed for a wide variety of applications, including the fabrication of integrated devices and microdevices. One method of processing substrates includes depositing a material, such as a semiconductor material or a conductive material, on an upper surface of the substrate. For example, epitaxy is one deposition process that deposits films of various materials on a surface of a substrate in a processing chamber. During processing, various parameters can affect the uniformity of material deposited on the substrate.

However, operations (such as epitaxial deposition operations) can be long, expensive, and inefficient, and can have limited capacity and throughput. Moreover, hardware can involve relatively large dimensions that occupy higher footprints in manufacturing facilities. Additionally, processing can involve non-uniformities, which can involve hindered device performance and/or reduced throughput. For example, activation of gases can be limited and/or can involve non-uniform activation, which can cause limited and/or non-uniform film growth and/or dopant concentration. The activation of gases can be limited, for example, at relatively low processing temperatures for device production (such as complementary field-effect transistor (CFET) devices). Moreover, relatively higher processing temperatures can involve unintended dopant diffusion and/or hindered device performance.

Therefore, a need exists for improved apparatuses and methods in semiconductor processing.

### SUMMARY

The present disclosure relates to heaters, and related chamber kits and processing chambers, for semiconductor manufacturing.

In one or more embodiments, a chamber body is disclosed. The chamber body includes an inject section and an exhaust section, a plasma source assembly, a substrate support disposed in the processing volume, and one or more heat sources configured to heat the processing volume. The chamber body and the plasma source assembly at least partially define a processing volume. The plasma source assembly includes a sidewall and a gas injection insert disposed within the sidewall. The sidewall and the gas injection insert define a plasma source interior volume. The gas injection insert and the sidewall at least partially defining one or more gas injection channels therebetween. A plasma generator is disposed around the sidewall

In one or more embodiments, a processing chamber applicable for use in semiconductor manufacturing. The processing chamber includes a chamber body including an inject section and an exhaust section, one or more heat sources, a lid comprising an opening, a first conductive plate, a second conductive plate, and a substrate support disposed in the processing volume. The one or more heat sources are disposed between the lid and the substrate support. The first conductive plate at least partially defines a processing volume. The first conductive plate and the second conductive plate at least partially define a remote processing volume.

In one or more embodiments, a method of substrate processing is disclosed. The method includes heating a substrate from a first side of the substrate. The substrate is positioned in a processing volume of a processing chamber. A plasma is supplied in a processing volume of a processing chamber from a second side of the substrate. One or more process gases are flowed over the substrate. One or more layers are deposited on the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic side cross-sectional view of a processing chamber, according to one or more embodiments.

FIG. 2 is a schematic side cross-sectional view of a processing chamber, according to one or more embodiments.

FIG. 3 is a schematic side cross-sectional view of a processing chamber, according to one or more embodiments.

FIG. 4 is a schematic side cross-sectional view of a processing chamber, according to one or more embodiments.

FIG. 5 is a schematic side cross-sectional view of a processing chamber, according to one or more embodiments.

FIG. 6 is a schematic side cross-sectional view of a processing chamber, according to one or more embodiments.

FIG. 7 is a schematic block diagram view of a method of substrate processing for semiconductor manufacturing, according

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to heaters, and related chamber kits and processing chambers, for semiconductor manufacturing.

The disclosure contemplates that terms such as “couples,” “coupling,” “couple,” and “coupled” may include but are not limited to bonding, embedding, welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

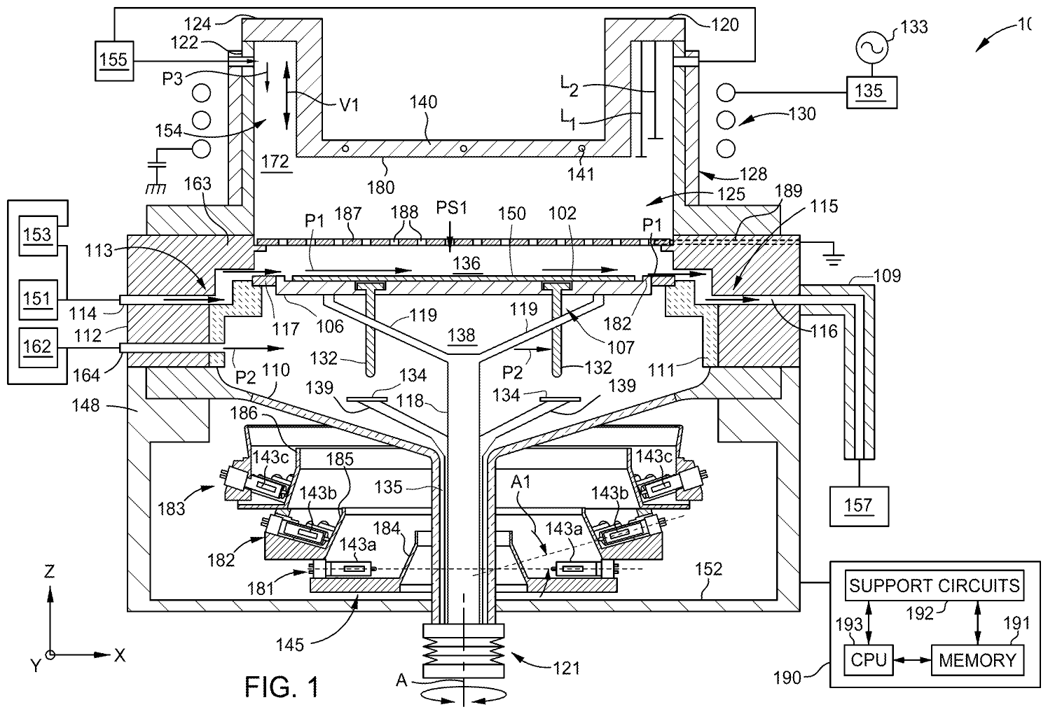

FIG. 1 is a schematic side cross-sectional view of a processing chamber 100, according to one or more embodiments. The processing chamber 100 is a deposition chamber. In one or more embodiments, the processing chamber 100 is a deposition chamber, such as an epitaxial deposition chamber. The processing chamber 100 is utilized to grow an epitaxial film on a substrate 102, and the processing chamber 100 is used to supply a plasma for plasma operations (such as plasma-assisted film deposition, ion supply into the substrate 102, pre-cleaning of the substrate 102, etching of the substrate 102, and/or cleaning of the processing chamber 100). In one or more embodiments, the processing chamber 100 creates a cross-flow of precursors across a top surface 150 of the substrate 102. The processing chamber 100 is shown in a processing condition in FIG. 1.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, a lower window 110 (such as a lower dome), and a plurality of heat sources 143. The window 110 is formed of an energy transmissive material, such as transparent quartz. In one or more embodiments, the heat sources 143 include lower lamps operable to heat a processing volume 136 from one side of the substrate 102 (e.g., from below the substrate 102). In one or more embodiments, the heat sources 143 include lamps (such as halogen lamps or UV lamps). The present disclosure contemplates that other heat sources may be used (in addition to or in place of the lamps) for the various heat sources described herein. For example, resistive heaters, light emitting diodes (LEDs), lasers (e.g., laser diodes), and/or or any other suitable heat source singly or in combination may be used for the various heat sources described herein.

The substrate support 106 is disposed in the processing volume 136 and between the upper body 156 and the window 110. The substrate support 106 is disposed above the one or more heat sources 143, and the substrate support 106 supports the substrate 102. In one or more embodiments, the substrate support 106 includes a susceptor. Other substrate supports (including, for example, a substrate carrier and/or one or more ring segment(s) that support one or more outer regions of the substrate 102) are contemplated by the present disclosure. The plurality of heat sources 143 are disposed between the window 110 and a floor 152. The plurality of heat sources 143 form a portion of a heat source module 145. The lower window 110 is a lower dome and/or is formed of an energy transmissive material, such as quartz.

A processing volume 136 and a purge volume 138 are formed between the upper body 156 and the lower window 110. The processing volume 136 and the purge volume 138 are part of an internal volume defined at least partially by the upper body 156, the lower window 110, and one or more liners 111, 163. The one or more liners 111, 163 are disposed inwardly of the chamber body.

The internal volume has the substrate support 106 disposed therein. The substrate support 106 includes a top surface on which the substrate 102 is disposed. The substrate support 106 is attached to a shaft 118. In one or more embodiments, the substrate support 106 is coupled to the shaft 118 through one or more arms 119 coupled to the shaft 118. The shaft 118 is coupled to a motion assembly 121. The motion assembly 121 includes one or more actuators and/or adjustment devices that provide movement and/or adjustment for the shaft 118 and/or the substrate support 106 within the processing volume 136.

The substrate support 106 may include lift pin holes 107 disposed therein. The lift pin holes 107 are each sized to accommodate a lift pin 132 for lifting of the substrate 102 from the substrate support 106 before or after a deposition process is performed. The lift pins 132 may rest on lift pin stops 134 when the substrate support 106 is lowered from a process position to a transfer position. The lift pin stops 134 can include a plurality of arms 139 that attach to a shaft 118.

The flow module 112 includes one or more gas inlets 114 (e.g., a plurality of gas inlets), one or more purge gas inlets 164 (e.g., a plurality of purge gas inlets), and one or more gas exhaust outlets 116. The one or more gas inlets 114 are part of an inject portion 113 of the chamber body, and the one or more gas exhaust outlets 116 are part of an exhaust portion 115 of the chamber body. The one or more gas inlets and the one or more purge gas inlets 164 are disposed on the opposite side of the flow module 112 from the one or more gas exhaust outlets 116. A pre-heat ring 117 is disposed below the one or more gas inlets 114 and the one or more gas exhaust outlets 116. The pre-heat ring 117 can include a complete ring or one or more ring segments. The pre-heat ring 117 is disposed above the one or more purge gas inlets 164. The one or more liners 111, 163 are disposed on an inner surface of the flow module 112 and protects the flow module 112 from reactive gases used during deposition operations and/or cleaning operations. The gas inlet(s) 114 and the purge gas inlet(s) 164 are each positioned to flow a respective one or more process gases P1 and one or more purge gases P2 parallel to the top surface 150 of a substrate 102 disposed within the processing volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. The one or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). The one or more purge gases P2 supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen (H) and/or chlorine (CI). In one or more embodiments, the one or more process gases P1 include silicon phosphide (SiP) and/or phospine (PH₃), and the one or more cleaning gases include hydrochloric acid (HCl).

The one or more gas exhaust outlets 116 are further connected to or include an exhaust system 109. The exhaust system 109 fluidly connects the one or more gas exhaust outlets 116 and the exhaust pump 157. The exhaust system 109 can assist in the controlled deposition of a layer on the substrate 102. The exhaust system 109 is disposed on an opposite side of the processing chamber 100 relative to the flow module 112.

The processing chamber 100 includes the one or more liners 111, 163 (e.g., a lower liner 111 and an upper liner 163). The flow module 112 (which can be at least part of a sidewall of the processing chamber 100) includes the one or more gas inlets 114 in fluid communication with the processing volume 136. The one or more gas inlets 114 are in fluid communication with one or more flow gaps between the upper liner 163 and a lower liner 111.

During a deposition operation (e.g., an epitaxial growth operation), the one or more process gases P1 flow through the one or more gas inlets 114, through the one or more gaps, and into the processing volume 136 to flow over the substrate 102.

The present disclosure also contemplates that the one or more purge gases P2 can be supplied to the purge volume 138 (through the one or more purge gas inlets 164) during the deposition operation, and exhausted from the purge volume 138. The one or more purge gases P2 flow simultaneously with the flowing of the one or more process gases P1. The one or more process gases P1 are exhausted through gaps between the upper liner 163 and the lower liner 111, and through the one or more gas exhaust outlets 116. The one or more purge gases P2 can be exhausted through one or more outlet openings, and through the one or more gas exhaust outlets 116 as the one or more process gases P1. The present disclosure contemplates that that the one or more purge gases P2 can be separately exhausted through one or more second gas exhaust outlets that are separate from the one or more gas exhaust outlets 116.

During a cleaning operation, one or more cleaning gases flow through the one or more gas inlets 114, through the one or more gaps (between the upper liner 163 and the lower liner 111), and into the processing volume 136.

The upper body 156 includes a plasma source assembly 120. A plasma can be generated in the plasma source assembly 120 (e.g., in a plasma generation region) by a plasma generator (e.g., an induction coil 130) and desired particle flow from the plasma source assembly 120 to the substrate 102 through openings 188 provided in a conductive plate 187 that separates the plasma source assembly 120 from the processing volume 136. The present disclosure contemplates that the conductive plate 187 can be omitted.

The plasma source assembly 120 includes a dielectric sidewall 122. The plasma source assembly 120 includes a top cover 124. The dielectric sidewall 122 and top cover 124, including an insert 140, define a plasma source interior 125. Dielectric sidewall 122 can include any suitable dielectric material, such as quartz. The induction coil 130 is disposed proximate (e.g., adjacent) the dielectric sidewall 122 about the plasma source assembly 120. The induction coil 130 is coupled to an RF power generator 133 through a matching network 135. Feed gas(es) P3 are introduced to the plasma source interior from a plasma gas supply 155. When the induction coil 130 is energized with RF power from the RF power generator 133, a plasma is generated in the plasma source assembly 120. In one or more embodiments, the plasma is generated using the plasma source assembly 120 in an inductively coupled plasma (ICP) manner. In one or more embodiments, RF power is provided to coil 130 at about 1 KW to about 15 kW, such as about 3 kW to about 10 KW. Induction coil 130 may ignite and sustain a plasma in a wide pressure and flow range. In one or more embodiments, the processing chamber 100 includes a grounded Faraday shield 128 to reduce capacitive coupling of the induction coil 130 to the plasma.

To increase efficiency, the processing chamber 100 includes a gas injection insert 140 disposed in the plasma source interior 125. The gas injection insert includes one or more cooling channels 141 configured to cool the gas injection insert 140 during the processing of the substrate 102. One or more gas injection channels 154 provide the process gas to the plasma source interior 125 through an active region 172, where due to enhanced confinement of hot electrons a reaction between hot electrons and the feed gas occurs. The reaction of can occur, for example, in the one or more gas injection channels 154 between the insert 140 and the dielectric sidewall 122 and/or the active region 172 described below. The one or more gas injection channels 154 extend annularly between the dielectric sidewall 122 and the insert 140. The feed gas(es) used to generate the plasma may include but is not limited to one or more of: hydrogen (H₂), xenon (Xe₂), fluorine (F₂), krypton fluoride (KrF), neon (Ne), and/or any mixtures thereof (such as xenon and neon). In one or more embodiments, the feed gas(es) includes one or more silicon-containing gases (e.g., silane, dichlorosilane (DCS), trichlorosilane (TCS), disilane (DS), and/or tetraclorosilane) mixed with a carrier gas (e.g., argon, hydrogen, and/or helium). In one or more embodiments, the feed gas(es) include one or more dopant gases, such as germane, diborane, and/or phosphorous. Other gases are contemplated as the feed gas(es). An enhanced electron confinement region or an active region 172 is defined by sidewalls of gas injection insert 140 and the dielectric sidewall 122 in radial direction and by the edge of a bottom surface 180 of the insert 140 from the bottom in the vertical direction. The active region 172 provides an electron confinement region within the plasma source interior 125 for efficient plasma generation and sustaining. The one or more gas injection channels 154 can be about 1 mm in width or greater, such as about 10 mm or greater, such as about 1 mm to about 10 mm. The gas injection insert 140 guides the process gas to be passed through the active region 172 where plasma is formed.

The capabilities of the gas injection insert 140 to improve efficiency of the processing chamber 100 are independent of the material of the gas injection insert 140 as long as the walls that are in direct contact with radicals are made of material with a low recombination rate for the radicals. For instance, in one or more embodiments, the gas injection insert 140 can be made from a metal, such as an aluminum material, with a coating configured to reduce surface recombination. In one or more embodiments, the gas injection insert 140 can be made of a dielectric material, such as a quartz material, or an insulative material.

The coil 130 is aligned with the active region 172 and/or the one or more gas channels 154 in such a way that the top turn of the coil 130 is above the bottom surface 180 of the insert 140 and operates substantially in the active region 172 of the inner volume and/or the one or more gas channels 154, while the bottom turn of the coil is below the bottom surface 180. The center of the coil 130 is substantially aligned with the bottom surface 180. The position of the coil 130 can be adjusted for a desired performance. Alignment of the coil 130 with bottom surface 180 provides improved source efficiency, namely controlled generation of desired chemical species for plasma processes and delivering them to the substrate 102 with reduced or eliminated losses. For example, plasma sustaining conditions (balance between local generation and loss of ions) can be enhanced in light of generating species for a plasma process. Regarding delivery of the species to the substrate 102, efficiency can depend on the volume and wall recombination of the species. Hence, control of the alignment of the coil 130 with bottom surface 180 provides control of the source efficiency for a plasma process.

In one or more embodiments, the coil 130 has a short transition region near the leads, and the remainder of the coil turns are parallel to the bottom surface 180. In one or more embodiments, the coil 130 is helical. In one or more embodiments, the coil 130 has 2-5 turns.

In one or more embodiments, bottom surface 180 is aligned with a portion of induction coil 130 (e.g., a coil loop) by utilizing a suitably sized insert 140 (and top cover 124, which may be a preformed part of the insert 140) to form the plasma source assembly 120. The bottom surface 180 can be movable along a vertical direction V1 relative to the plasma source assembly 120 while a remainder portion of insert 140 is static (e.g., fixed) as part of plasma source assembly 120, in order to provide alignment of bottom surface 180 with a portion of the coil 130. For example, a mechanism can be coupled with a portion of insert 140 to adjust a position of bottom surface 180 such that a portion of insert 140 having a first length (L1) is adjusted relative to a second length (L2). The mechanism can be for example an actuator, for example a motor, electric motor, stepper motor, or pneumatic actuator. Other mechanisms are contemplated. In one or more embodiments, a difference (Δ) in length from L1 to L2 is about 0.1 cm to about 4 cm, such as about 1 cm to about 2 cm.

The insert 140 can be coupled to a mechanism, and the mechanism is configured to move the entirety of insert 140 vertically (e.g., along a vertical direction V1 relative to plasma source assembly 120), in order to align bottom surface 180 with a portion of coil 130. Spacers (not shown) can be used to fill gap(s) between insert 140 and another portion of plasma source assembly 120 (such as between top cover 124 and dielectric sidewall 122) that were formed by moving the insert vertically. The spacers may be formed from, for example, a ceramic material, such as a quartz.

In general, positioning a center of the coil 130 above bottom surface 180 can increase the efficiency of ionization and dissociation, but reduces the transport efficiency of species to the substrate, as many of the species may recombine on the walls of the narrow active region. Positioning the coil 130 below bottom surface 180 can improve plasma delivery efficiency, but may decrease plasma generation efficiency.

Conductive plate 187 is configured to separate a processing volume 136 from plasma charged particles (ions and electrons), which recombine on the conductive plate 187, so that neutral plasma species can pass through the conductive plate 187 into the processing volume 136 while other species are blocked. The conductive plate 187 is formed of a conductive material. In one or more embodiments, the conductive material includes silicon carbide (SIC), molybdenum, tungsten, stainless steel, and/or aluminum (such as anodized aluminum). In one or more embodiments, conductive plate 187 has a plurality of openings 188. The openings 188 are disposed through the conductive plate 187 (e.g., openings 188 traverse the thickness of the conductive plates 187). The openings 188 in the bottom section of the conductive plate 187 may have a different pattern. Openings 188 may have an average diameter of about 4 mm to about 6 mm. In one or more embodiments, the conductive plate 187 has a thickness of about 5 mm to about 10 mm, which defines the opening 188 length (L1). A ratio of the conductive plate 187 thickness (length (L1)) to the average diameter of the plurality of openings 188 may be greater than about 1, such as about 1 to about 3. The conductive plate 187 can function as an ion filter (e.g., an ion blocker plate) such that, as the plasma flows past the conductive plate 187, radicals flow through the flow openings 188 and past the conductive plate 187 while ions are at least partially blocked by the conductive plate 187 and conduct through the conductive plate and to ground through a ground electrode 189. The ground electrode 189 extends into the conductive plate 187 on a side aligned with the exhaust portion 115 of the processing chamber 100.

The plasma PS1 can be supplied in the processing volume 136 during the flowing of the one or more process gases P1 (and/or the cleaning gases) to facilitate breaking bonds, e.g., for deposition on the substrate 102. The plasma PS1 can be supplied in the processing volume 136 before the flowing of the one or more process gases P1 (e.g., to pre-clean the substrate 102), or after the flowing of the one or more process gases P1 (e.g., to etch the substrate 102, supply ions into the substrate 102, and/or to clean the processing chamber 100). The present disclosure also contemplates that the plasma PS1 can be supplied through the one or more gas inlets 114.

As shown, a controller 190 is in communication with the processing chamber 100 and is used to control processes and methods, such as the operations of the methods described herein. The controller 190 is configured to receive data or input as sensor readings from sensor(s). The sensor devices can include, for example: sensor devices that monitor growth of layer(s) on the substrate 102; and/or sensor devices that monitor temperatures of the substrate 102, the one or more heaters, the substrate support 106, and/or the liners 111, 163. As an example, one or more sensor devices can measure temperatures o and power to one or more heaters can be controlled based on the measured temperatures (e.g., using a feedback control). As described the one or more sensor devices can include, for example pyrometers. In one or more embodiments, one or more thermocouples (e.g., proximity thermocouples) are disposed to measure the temperatures and power to the one or more heaters can be controlled based on the measured temperatures (e.g., using a feedback control). As an example, one or more of the sensor devices can measure one or more gas parameters and/or one or more plasma parameters (such as ion density, electron temperature, electron density, energy distribution, enthalpy, and/or absorption). In one or more embodiments, one or more of the sensor devices include a residual gas analyzer, an optical emission spectrometer, an enthalpy probe, a Langmuir probe, Faraday cup, and/or an absorption spectrometer.

The controller 190 includes a central processing unit (CPU) 193 (e.g., a processor), a memory 191 containing instructions, and support circuits 192 for the CPU 193. The controller 190 controls various items directly, or via other computers and/or controllers. In one or more embodiments, the controller 190 is communicatively coupled to dedicated controllers, and the controller 190 functions as a central controller.

The controller 190 is of any form of a general-purpose computer processor that is used in an industrial setting for controlling various substrate processing chambers and equipment, and sub-processors thereon or therein. The memory 191, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like. Operational parameters (e.g., a power applied to the coil 130, a power applied to the heat sources 143, a cleaning recipe, and/or a processing recipe) and operations are stored in the memory 191 as a software routine that is executed or invoked to turn the controller 190 into a specific purpose controller to control the operations of the various chambers/modules described herein. The controller 190 is configured to conduct any of the operations described herein. The instructions stored on the memory, when executed, cause one or more of the operations (such as operations of the method 700) described herein to be conducted in relation to the processing chamber 100. The controller 190 and the processing chamber 100 are at least part of a system for processing substrates.

The various operations described herein can be conducted automatically using the controller 190, or can be conducted automatically or manually with certain operations conducted by a user.

The controller 190 is configured to control power to one or more heaters, power to the coil 130, the deposition, the cleaning, the rotational position, the heating, and gas flow through the processing chamber 100 by providing an output to the controls for the sensor devices, the one or more heaters, the RF power generator 133, the heat sources 143, the process gas source 151, the purge gas source 162, the plasma gas supply 155, the motion assembly 121, and/or the exhaust pump 157.

During processing, in one or more embodiments, the substrate 102 is heated. The one or more heat sources 143 include a plurality of heat sources 143a-143c arranged in a plurality of levels 181-183. The plurality of levels 181-183 includes a first level 181 of one or more first heat sources 143a and a second level 182 of one or more second heat sources 143b oriented at an angle A1 (e.g., an oblique angle) relative to the first level 181. The plurality of levels 183 include a third level 183 of one or more third heat sources 143c. The processing chamber 100 includes a first reflector 184 disposed inwardly of the first level 181 of one or more first heat sources 143a, a second reflector 185 disposed inwardly of the second level 182 of one or more second heat sources 143b, and a third reflector 186 disposed inwardly of the third level 183 of one or more third heat sources 143c. The plurality of heat sources 143a-143c are arranged in a plurality of zones 186-188 (three zones are shown in FIG. 1). In one or more embodiments, the first level 181 of one or more first heat sources 143a are oriented perpendicularly to a longitudinal axis of the substrate support 106, and the second level 182 of one or more second heat sources 143b and the third level 183 of one or more third heat sources 143c are oriented at an oblique angle relative to the longitudinal axis.

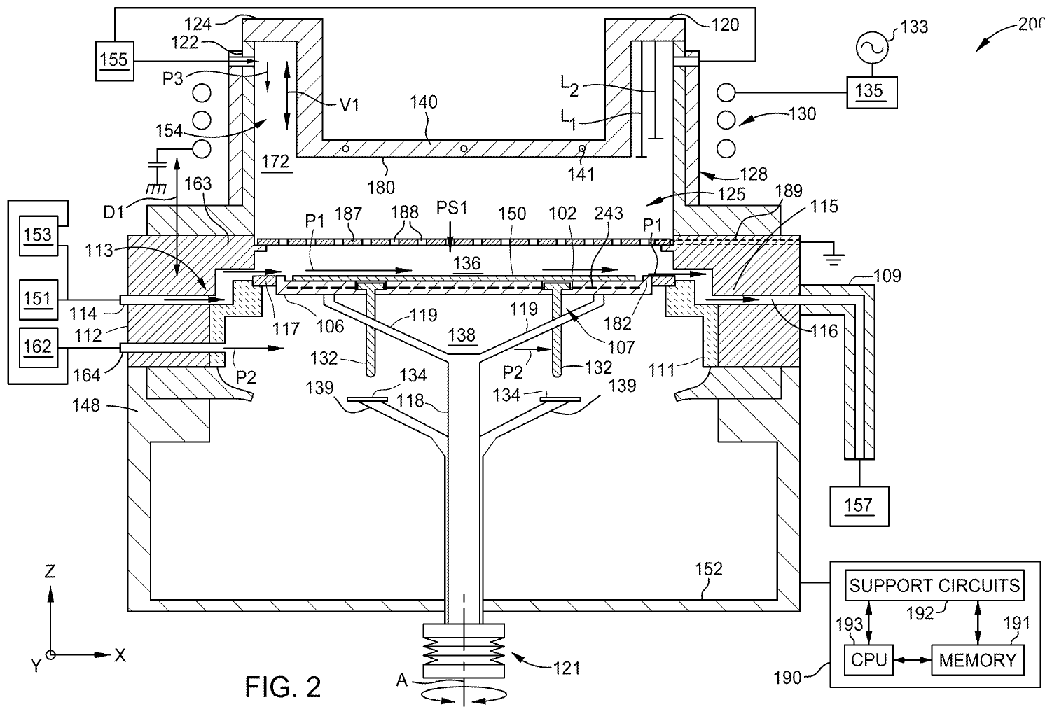

FIG. 2 is a schematic side cross-sectional view of a processing chamber 200, according to one or more embodiments. The processing chamber 200 is similar to the processing chamber 100 shown in FIG. 1, and includes one or more aspects, features, components, operations, and/or properties thereof.

The processing chamber 200 omits the heat source module 145 shown in FIG. 1. In one or more embodiments, the processing chamber 200 does not include a heat source module disposed below the substrate 102. The substrate support 106 includes a heater 243 disposed within the substrate support 106. The heater 243 may be a resistive heater. The present disclosure contemplates that a heat source module can be used in addition to the resistive heater. The heater 243 is configured to heat the substrate 102 disposed on the substrate support 106.

The substrate support 106 is a first distance D1 from the induction coil 130. The first distance D1 is from about 5 cm to about 15 cm. The resistive heater 243 enables a more compact processing chamber 200. The temperature of the substrate 102 can be controlled by moving the substrate 102 away from the substrate support 106 are different pressures and temperature ranges. The resistive heater 243 may include a multi-zone resistive heater with model-based control. The temperature zones of the multi-zone resistive heater can be controlled with embedded thermocouples. The embedded thermocouples monitor the temperatures across the temperature zones to allow adjustment of the temperatures in the temperature zones during processing.

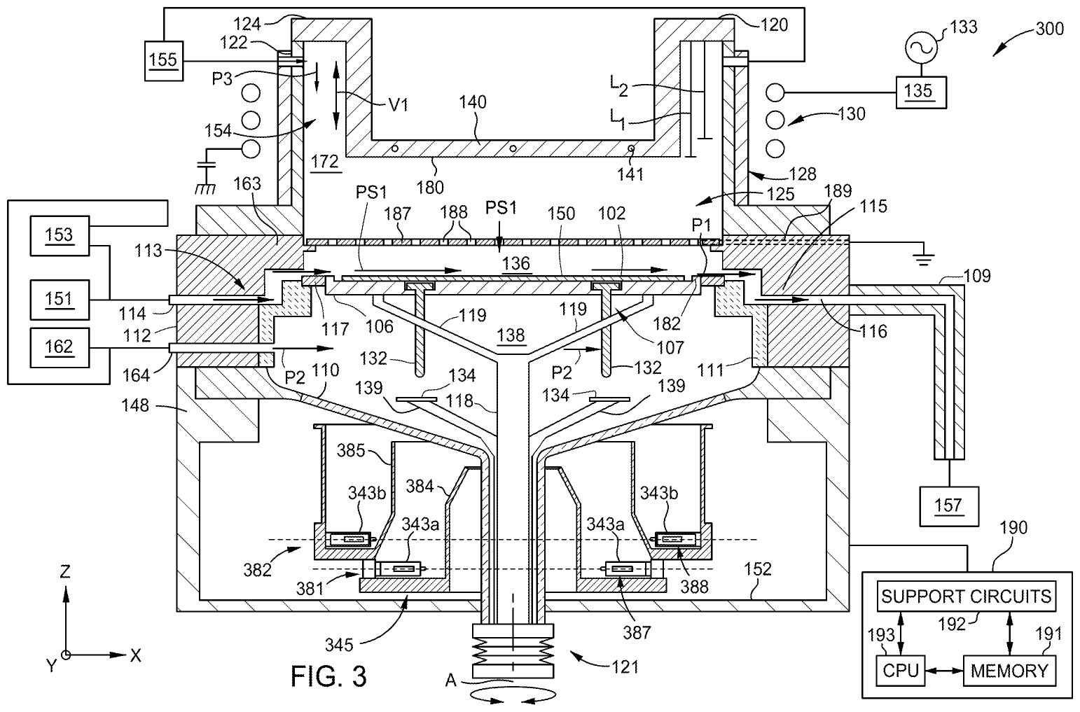

FIG. 3 is a schematic side cross-sectional view of a processing chamber 300, according to one or more embodiments.

The processing chamber 300 is similar to the processing chamber 100 shown in FIG. 1, and includes one or more aspects, features, components, operations, and/or properties thereof.

The processing chamber 300 includes a heat source module 345 disposed below the substrate support 106. The heat source module 345 includes one or more heat sources 343. The one or more heat sources 343 include a plurality of heat sources 343a-343b arranged in a plurality of levels 381, 382. The plurality of levels 381, 382 includes a first level 381 of one or more first heat sources 343a and a second level 382 of one or more second heat sources 343b oriented parallel to the first level 381. The heat source module 345 of the processing chamber 300 includes a first reflector 384 disposed inwardly of the first level 381 of one or more first heat sources 343a, a second reflector 385 disposed inwardly of the second level 382 of one or more second heat sources 343b. The plurality of heat sources 343a, 343b are arranged in a plurality of zones 387, 388 (two zones are shown in FIG. 3). In one or more embodiments, the first level 381 of one or more first heat sources 343a and the second level 382 of one or more second heat sources 343b are oriented perpendicularly to the longitudinal axis of the substrate support 106.

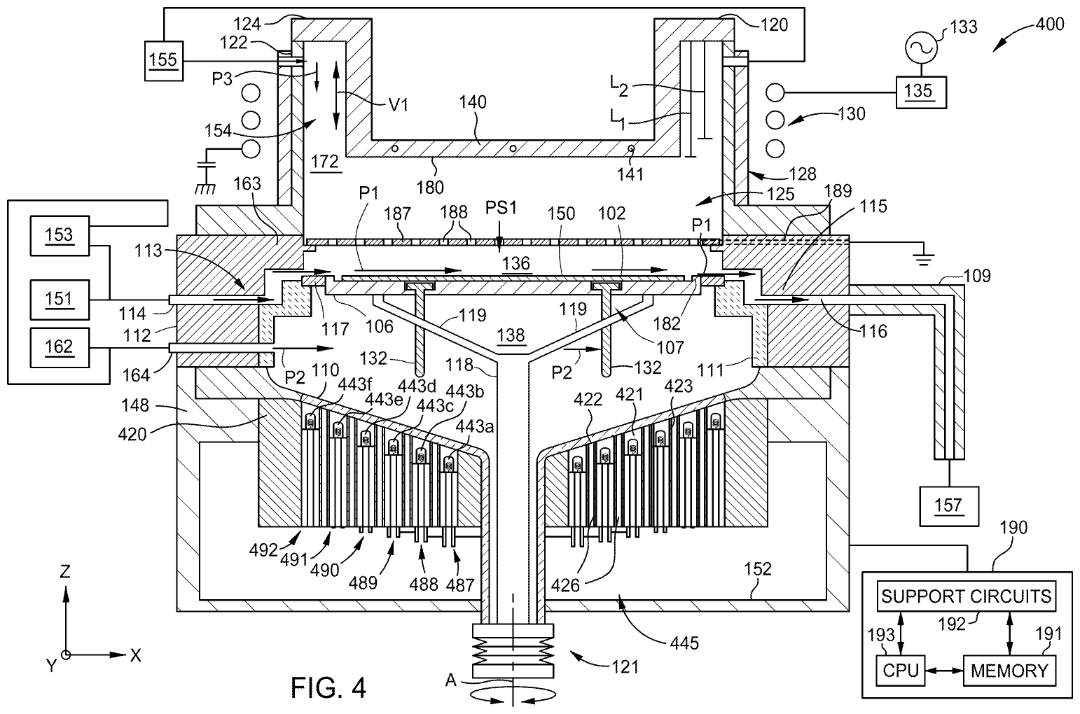

FIG. 4 is a schematic side cross-sectional view of a processing chamber 400, according to one or more embodiments.

The processing chamber 400 is similar to the processing chamber 100 shown in FIG. 1, and includes one or more aspects, features, components, operations, and/or properties thereof.

The processing chamber 400 includes a heat source module 445 disposed below the substrate support 106. The heat source module 445 includes one or more heat sources 443. The one or more heat sources 443 include a plurality of heat sources 443a-443f arranged in a plurality of zones 487-492 (six zones are shown in FIG. 4). The heat source module 345 of the processing chamber 400 includes a reflector housing 420, and the heat sources 443a-443f are disposed respectively in openings 421 of the reflector housing 420. The reflector housing 420 can be formed of a reflective material (such as gold or polished aluminum) and/or can be coated with the reflective material. For example, an upper surface 422 and/or interior surfaces 423 adjacent the openings 421 can be coated with the reflective material. A plurality of cooling channels 426 are formed in the reflector housing 420 and between the respective openings 421. The cooling channels 426 can receive a cooling fluid, such as air or water. In one or more embodiments, the plurality of heat sources 443a-443f are oriented parallel to the longitudinal axis of the substrate support 106. The reflective material and/or the reflectors described herein can have a reflectivity greater than about 90%, such as greater than about 98% for wavelengths of about 150 nm or higher, such as 150 nm to about 15000 nm, such as about 700 nm to about 15000 nm, about 700 nm to 1000 nm, or about 1000 nm to about 15000 nm. In one or more embodiments, the reflective material and/or the reflectors described herein can have a reflectivity greater than about 90%, such as greater than about 98% for wavelengths in the infrared range and/or the ultraviolet range.

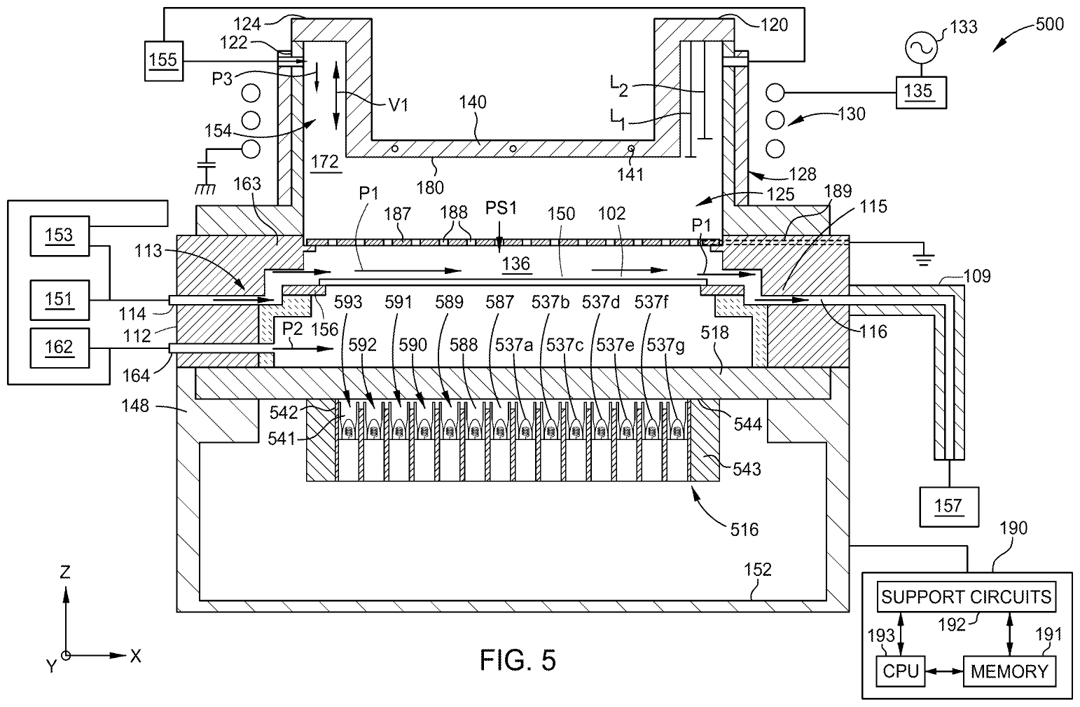

FIG. 5 is a schematic side cross-sectional view of a processing chamber 500, according to one or more embodiments.

The processing chamber 500 is similar to the processing chamber 100 shown in FIG. 1 and/or the processing chamber 400 shown in FIG. 4, and includes one or more aspects, features, components, operations, and/or properties thereof.

The processing chamber 500 includes a chamber body at least partially defining the processing volume 136 to process the substrate 102. The chamber body may be made of stainless steel and may be lined with quartz. The processing volume 136 is configured to be radiantly heated by a heat source module 516 disposed under a quartz window 518. In one or more embodiments, the quartz window 518 is fluid cooled.

The heat source module 516 includes one or more heat sources. The one or more heat sources include a plurality of heat sources 537a-537g arranged in a plurality of zones 587-593 (seven zones are shown in FIG. 5). The heat source module 516 of the processing chamber 500 includes a reflector housing 543, and the heat sources 537a-537g are disposed respectively in openings 541 of the reflector housing 543. The openings 541 are oriented parallel (e.g., vertically) to the longitudinal axis of the substrate support 106. The reflector housing 543 can be formed of the reflective material and/or can be coated with the reflective material. For example, an upper surface 544 and/or interior surfaces 542 adjacent the openings 541 can be coated with the reflective material. Portions of the reflector housing 543 are between the openings 541. One or more cooling channels can be formed in the reflector housing 543. In one or more embodiments, the plurality of heat sources 537a-537g are oriented parallel to the longitudinal axis of the substrate support 106.

The heat sources connected to the controller 190 are capable of adjusting heating effects of the heat sources. In one or more embodiments, the heat sources are grouped into the zones 587-593, and the zones 587-593 of the heat sources can be independently powered using the controller 190. Zones 587-593 may be controlled independently to provide a target temperature profile across the substrate 102. The zones 587-593 of the heat sources can be independently pulsed. The zones 587-593 can be connected to a respective power source that can be individually controlled. In one or more embodiments, the amplitude, phase, and/or frequency of power provided to the respective zones 587-593 may be independently controlled to adjust radiant energy directed to a corresponding zone of the substrate 102.

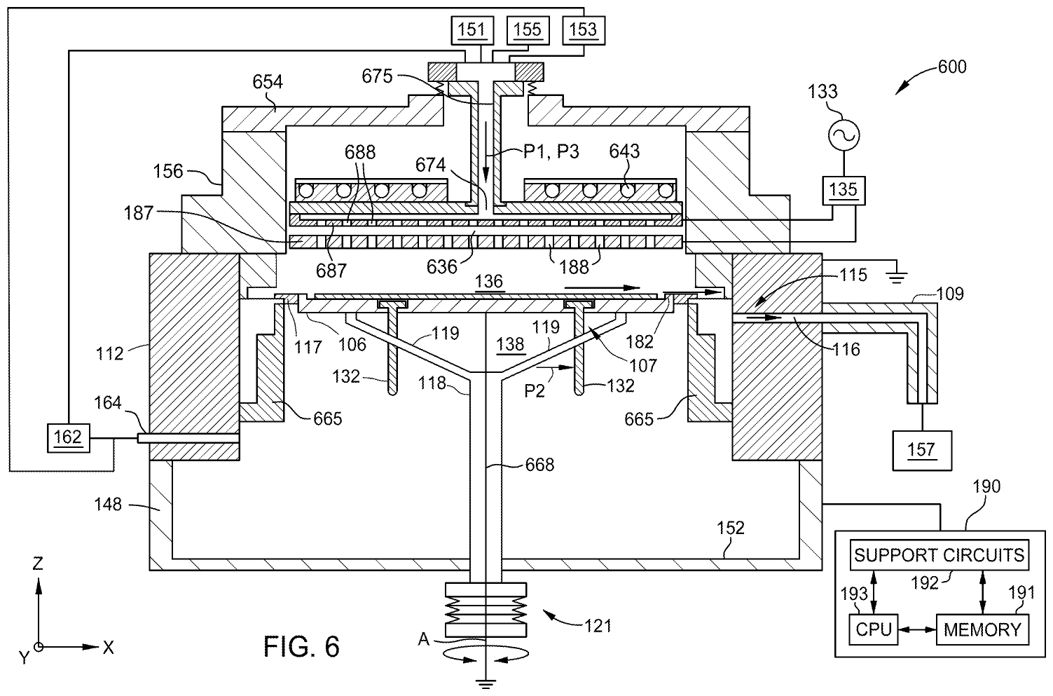

FIG. 6 is a schematic side cross-sectional view of a processing chamber 600, according to one or more embodiments.

The processing chamber 600 is similar to the processing chamber 100 shown in FIG. 1, and includes one or more aspects, features, components, operations, and/or properties thereof.

The processing chamber 600 includes a chamber body at least partially defining the processing volume 136 to process the substrate 102. The upper body 156 includes a lid 654, a first conductive plate 187, a second conductive plate 687, heat sources 643, an opening 674, and a conduit 675. The first conductive plate 187 and the substrate support 106 define a processing volume 136. The first conductive plate 187 and the second conductive plate 687 define a remote processing volume 636. The first conductive plate 187 includes the first openings 188. The second conductive plate 687 includes one or more second openings 688.

The feed gas P3 can be supplied into the remote processing volume 636 and the processing volume 136 from the plasma gas supply 155. The feed gas P3 can be generated into a plasma within the remote processing volume 636 or the processing volume 136. In one or more embodiments, the plasma is generated in a capacitively coupled plasma (CCP) manner. The processing chamber 600 is configured to generate the plasma in the remote processing volume 636 or the processing volume 136. During plasma generation in the remote processing volume 636, RF power is supplied to the first conductive plate 187 to heat the first conductive plate 687 to generate the plasma from the processing gas P2. In one or more embodiments, a bias is not provided to the second conductive plate 687 and the substrate 102 disposed on the substrate support 106. The bias provided to the first conductive plate 187 prevents ions and electrons from being supplied to the substrate 102, e.g., the substrate 102 is supplied neutral radicals.

During plasma generation in the processing volume 136, RF power is supplied to the first conductive plate 187 and the second conductive 687 to heat the first conductive plate 187 and the second conductive 687 to generate the plasma from the processing gas P2. In one or more embodiments, a bias is not provided to the substrate 102 disposed on the substrate support 106. The bias provided to the first conductive plate 187 and the second conductive 687 enables the substrate 102 to be supplied neutral radicals, ions, and electrons. The substrate 102 is grounded. For example, the substrate 102 can be grounded through a conductive line 668 connected to the substrate support 106 and extending through the shaft 118.

The processing chamber 600 can include or omit the one or more gas inlets 114, and the process gas P1 can flow through the same path as the feed gas P3. Before, during, and/or after the flow of the feed gas P3, the process gas P1 is supplied through the remote processing volume 636, through the processing volume 136, and over the substrate 102.

The lower body 148 further includes a pumping ring 665. The pumping ring 665 enables gases go to exhaust outlets 116 in a symmetric manner. The pumping ring 665 equalizes the conductance between exhaust outlets 116 and the regions all around the substrate 102 so that even if the exhaust outlets 116 is at one side of the chamber, the substrate 102 doesn't see an asymmetry of the gas flow. The pumping ring 665 mitigates asymmetry in the overall architecture of the processing chamber 600 in terms of flow path from the conduit 675 to the exhaust outlets 116. The pumping ring 665 is used to exhaust the gases (such as the process gas P1, the purge gas P2, and/or the plasma).

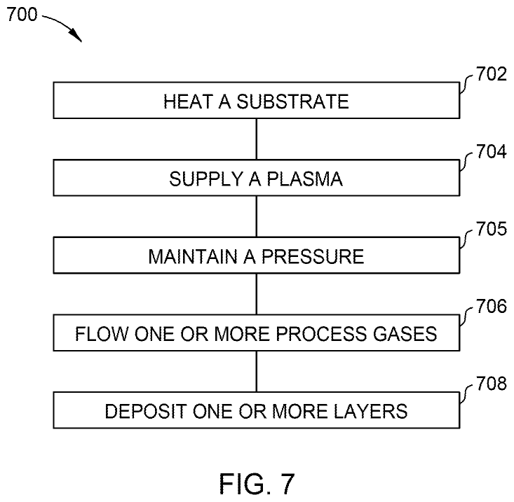

FIG. 7 is a schematic block diagram view of a method 700 of substrate processing for semiconductor manufacturing, according to one or more embodiments.

Operation 702 of the method 700 includes heating a substrate 102 positioned on the substrate support 106 of the processing chamber 100, 200, 300, 400, 500, 600. The substrate 102 is heated from one side of the substrate 102. The heating includes heating the substrate 102 to a target temperature. In one or more embodiments, the target temperature for the substrate 102 is less than 500 degrees Celsius. In one or more embodiments, the target temperature is 400 degrees Celsius or less, such as less than 200 degrees Celsius (for example about 150 degrees Celsius). In one or more embodiments, the target temperature for the substrate 102 is 400 degrees Celsius or higher or 600 degrees Celsius or less. In one or more embodiments, the target temperature for the substrate 102 is within a range of 380 degrees Celsius to 600 degrees Celsius, for example 400 degrees Celsius to 500 degrees Celsius.

Operation 704 includes supplying a plasma in the processing volume 136 of the processing chamber 100, 200, 300, 400, 500, 600. The plasma can be generated in the processing volume and/or can be generated outside of the processing volume and then flowed into the processing volume.

Operation 705 includes maintaining the processing volume at a pressure. In one or more embodiments, the pressure is maintained to be less than 60 Torr, such as within a range of 0 Torr to 30 Torr. In one or more embodiments, the pressure is maintained to be less than 1 Torr, such as within a range of 0 Torr to 5 m Torr.

Operation 706 includes flowing one or more process gases over the substrate 102. In one or more embodiments, the plasma of operation 704 is supplied during the flowing of the one or more process gases of operation 706, and the plasma flows over the substrate 102. In one or more embodiments, the plasma of operation 704 is supplied before or after the flowing of the one or more process gases of operation 706.

Operation 708 includes depositing one or more layers on the substrate 102. In one or more embodiments, the plasma of operation 704 is supplied during the depositing of operation 708. In one or more embodiments, the plasma of operation 704 is supplied before or after the depositing of operation 708.

Benefits of the present disclosure include reliable gas activation (such as at relatively low processing temperatures); adjustability of gas activation; modularity of using plasma operations and epitaxial deposition operations in a single chamber; modularity in chamber application; more uniform gas activation; temperature uniformity (e.g., temperature uniformity in an outer region of the substrate); reduced gas consumption and gas waste; increased growth rates; and more uniform film growth and/or dopant concentration. As an example, ions and/or radicals can be used to activate gases for processing in addition to or in place of electromagnetic radiation (such as infrared radiation and/or ultraviolet radiation).

Benefits also include enhanced device performance; reduced or eliminated occurrences of unintended dopant diffusions; efficient processing; and increased throughput. As an example, the gas activation is facilitated for substrate target temperatures less than 500 degrees Celsius, such as target temperatures within a range of 380 degrees to 500 degrees Celsius. For example, gas can be activated for processing operations when the substrate is at about 400 degrees Celsius.

It is contemplated that one or more aspects disclosed herein may be combined. As an example, one or more aspects, features, components, operations and/or properties of the processing chamber 100, the processing chamber 200, the processing chamber 300, the processing chamber 400, the processing chamber 500, the processing chamber 600, and/or the method 700 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing chamber applicable for use in semiconductor manufacturing, comprising:
a chamber body comprising an inject section and an exhaust section;
a plasma source assembly, the chamber body and the plasma source assembly at least partially defining a processing volume, the plasma source assembly comprising:
a sidewall;
a gas injection insert disposed within the sidewall, the sidewall and the gas injection insert defining a plasma source interior volume, the gas injection insert and the sidewall at least partially defining one or more gas injection channels therebetween; and
a plasma generator disposed around the sidewall;
a substrate support disposed in the processing volume; and
one or more heat sources configured to heat the processing volume.

2. The processing chamber of claim 1, wherein the one or more heat sources comprise a plurality of heat sources arranged in a plurality of levels and disposed below the substrate support.

3. The processing chamber of claim 2, wherein the plurality of levels comprise:
a first level of one or more first heat sources; and
a second level of one or more second heat sources oriented at an angle relative to the first level.

4. The processing chamber of claim 3, further comprising:
a first reflector disposed inwardly of the first level of one or more first heat sources; and
a second reflector disposed inwardly of the second level of one or more second heat sources.

5. The processing chamber of claim 1, wherein the one or more gas injection channels extend annularly between the sidewall and the gas injection insert.

6. The processing chamber of claim 1, wherein the one or more heat sources comprise a resistive heater disposed in the substrate support.

7. The processing chamber of claim 1, further comprising a conductive plate disposed between the substrate support and the gas injection insert, wherein the conductive plate comprises a plurality of flow openings.

8. The processing chamber of claim 7, further comprising an electrode extending into the conductive plate on a side aligned with the exhaust section of the processing chamber.

9. The processing chamber of claim 1, wherein the plasma generator comprises an induction coil.

10. The processing chamber of claim 1, wherein the one or more heat sources comprise a plurality of heat sources arranged in a plurality of zones.

11. The processing chamber of claim 10, wherein the plurality of heat sources are oriented parallel to a longitudinal axis of the substrate support.

12. The processing chamber of claim 10, wherein the plurality of heat sources are oriented at an oblique angle relative to a longitudinal axis of the substrate support.

13. A processing chamber applicable for use in semiconductor manufacturing, comprising:
a chamber body comprising an inject section and an exhaust section;
one or more heat sources;
a lid comprising an opening;
a first conductive plate, wherein the first conductive plate at least partially defines a processing volume;
a second conductive plate, wherein the first conductive plate and the second conductive plate at least partially define a remote processing volume; and
a substrate support disposed in the processing volume, the one or more heat sources disposed between the lid and the substrate support.

14. The processing chamber of claim 13, wherein the processing chamber is configured to generate a plasma in the remote processing volume.

15. The processing chamber of claim 13, wherein the processing chamber is configured to generate a plasma in the processing volume.

16. The processing chamber of claim 13, wherein the processing chamber includes a pumping ring disposed below the substrate support.

17. The processing chamber of claim 13, further comprising a pumping ring, wherein the pumping ring is radially symmetric around the substrate support.

18. A method of substrate processing, comprising:
heating a substrate from a first side of the substrate, the substrate positioned in a processing volume of a processing chamber;
supplying a plasma in a processing volume of a processing chamber from a second side of the substrate;
flowing one or more process gases over the substrate; and
depositing one or more layers on the substrate.

19. The method of claim 18, wherein the plasma is supplied during the flowing of the one or more process gases, and the plasma flows over the substrate.

20. The method of claim 18, wherein the plasma is supplied before or after the flowing of the one or more process gases.
